(19) United States
(12) Patent Application Publication
(10) Pub. No.: US 2025/0246576 A1
(43) Pub. Date: Jul. 31, 2025

(54) ELECTRONIC DEVICE AND A METHOD FOR FORMING THE SAME

(71) Applicant: JCET STATS ChipPAC Korea Limited, Incheon (KR)

(72) Inventors: YeoJun YUN, Incheon (KR); SeungHyun LEE, Incheon (KR); HeeSoo LEE, Incheon (KR); YoungHoon JEON, Incheon (KR)

(21) Appl. No.: 19/034,502

(22) Filed: Jan. 22, 2025

(30) Foreign Application Priority Data
Jan. 25, 2024 (CN) 202410108878.0

(51) Int. Cl. H01L 23/00; H01L 21/56; H01L 21/687

(52) U.S. Cl. CPC H01L 24/81; H01L 21/56; H01L 21/68714; H01L 24/11; H01L 24/13; H01L 24/16; H01L 2224/11849; H01L 2224/13111; H01L 2224/13113; H01L 2224/13116; H01L 2224/13124; H01L 2224/13139; H01L 2224/13144; H01L 2224/13147; H01L 2224/13155; H01L 2224/133; H01L 2224/13564; H01L 2224/13599; H01L 2224/16225; H01L 2224/8122; H01L 2924/3511

(57) ABSTRACT

An electronic device and a method for forming the same are provided. The method comprises: providing a substrate having a front surface, wherein the substrate comprising at least a non-polar material; providing at least one electronic component with solder bumps mounted on its back surface, wherein the solder bumps are coated with a flux material of at least a polar material, and the at least one electronic component comprises at least a non-polar material; disposing the at least one electronic component onto the front surface of the substrate via the solder bumps; and applying microwave radiation to the at least one electronic component to heat the solder bumps through the flux material.

### TECHNICAL FIELD

The present application generally relates to semiconductor technology, and more particularly, to an electronic device and a method for forming the same.

### BACKGROUND OF THE INVENTION

The semiconductor industry is constantly faced with complex integration challenges as consumers want their electronics to be smaller, faster and higher performance with more and more functionalities packed into a single device. Typically, electronic components are mounted onto a substrate via solder bumps. The formation of the solder bumps may include a reflowing process, which enables efficient electrical connection between the substrate and the electronic components thereon. The reflowing process can be conducted by applying thermal convection heating to the entire device where the solder bumps are formed. However, due to mismatch in the coefficient of thermal expansion (CTE) between different materials within the device, the heating process by convection heat transfer may induce warpage issues, which may adversely affect device performance and following fabrication processes.

Therefore, a need exists for further improvement of a method for forming an electronic device.

### SUMMARY OF THE INVENTION

An objective of the present application is to provide an improved method for forming an electronic device.

According to an aspect of the present application, an electronic device and a method for forming the same is provided. The method comprises: providing a substrate having a front surface, wherein the substrate comprises at least a non-polar material; providing at least one electronic component with solder bumps mounted on its back surface, wherein the solder bumps are coated with a flux material of at least a polar material, and the at least one electronic component comprises at least a non-polar material; disposing the at least one electronic component onto the front surface of the substrate via the solder bumps; and applying microwave radiation to the at least one electronic component to heat the solder bumps through the flux material.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain the principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIGS. 1A to 1F illustrate various steps of a method for forming an electronic device according to a first embodiment of the present application.

FIG. 2 illustrates a microwave radiation step of a method for forming an electronic device according to a second embodiment of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature's relationship to another element(s) or feature(s) as illustrated in the Figures. The spatially relative terms are intended to encompass different orientations of the device in use or operation in addition to the orientation depicted in the Figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

As mentioned above, electronic components are generally mounted onto a substrate via solder bumps. The formation of the solder bumps may include a reflowing process, which enables efficient electrical connection between the substrate and the electronic components thereon. The reflowing process may be conducted by applying thermal convection heating to the entire device where the solder bumps are formed. However, due to mismatch in the coefficient of thermal expansion (CTE) between different materials within the device, the heating process by convention heat transfer may induce warpage issues, which may adversely affect device performance and following fabrication processes. To address this issue, a new method for forming an electronic device is provided. The new method applies microwave radiation to heat the solder bumps through a flux material, which reduces warpage issues of the electronic device, especially when the device is within a substrate strip before a singulation process. The method can be used in forming an electronic device with a reduced size and a more complex structure, such as a system-in-package (SIP) device with various electronic components.

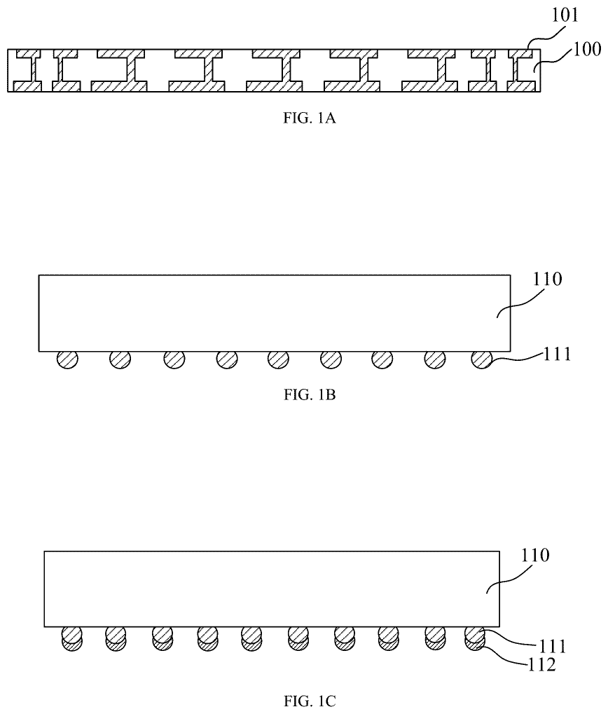

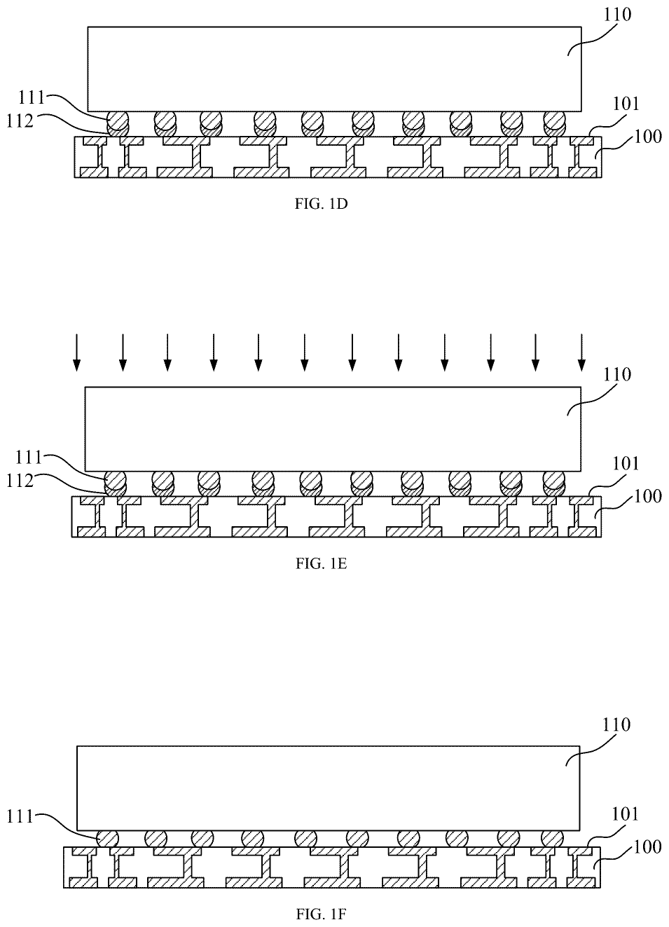

FIGS. 1A to 1F illustrate various steps of a method for forming an electronic device according to a first embodiment of the present application. In the following, the method will be described with reference to FIGS. 1A to 1F in more details.

As shown in FIG. 1A, a substrate 100 is provided with embedded interconnect wires 101. The substrate 100 includes a front surface, which may serve as a platform where electronic component(s) can be mounted. Multiple sets of conductive pads (not shown) can be formed on the front surface of the substrate 100 for the mounting of the electronic components. It can be appreciated that the multiple sets of conductive pads may be exposed portions of interconnect wires 101 formed within the substrate 100.

In the embodiment shown in FIG. 1A, the substrate 100 includes at least a non-polar material, such as silicon, which is the main part of the material of the substrate 100. It should be noted that the substrate 100 may also contain a minor amount of polar materials. For example, in this embodiment, the substrate 100 may contain more than 99 wt. % of non-polar material(s) and less than 1 wt. % of polar materials, which may be helpful to improve structural and electrical performances of the substrate 100. In some other embodiments, the substrate 100 may contain less than 2 wt. %, 5 wt. % or 10 wt. %. of polar materials.

As shown in FIG. 1B, at least one electronic component 110 is provided. In some embodiments, the electronic component(s) 110 may include various types of electronic modules, such as semiconductor chips, resistors, capacitors or the like. In an alternative embodiment, the at least one electronic component 110 may include a semiconductor package. For example, the semiconductor package may contain a package substrate, at least one electronic module mounted on the package substrate and a mold cap encapsulating the at least one electronic module. It can be appreciated that the electronic component(s) 110 may be arranged and sized according to actual needs of the electronic device. In some embodiments, different types of the electronic components 110 may be included in a single electronic device, depending on actual needs. Furthermore, the at least one electronic component 110 includes at least a non-polar material. It can be appreciated that, similar to the substrate 100 which is illustrated in FIG. 1A, the electronic component 110 may contain a minor amount of polar materials, such as encapsulates or adhesives within the electronic component 110. For example, the electronic component 110 may contain more than 99 wt. %, 98 wt. %, 95 wt. % or 90 wt. % of non-polar material(s), and accordingly less than 1 wt. %, 2 wt. %, 5 wt. % or 10 wt. %. of polar materials.

Next, a solder material is deposited onto a back surface of the electronic component 110 to form a plurality of solder bumps 111 on the multiple sets of conductive pads. In some embodiments, the solder bumps 111 may include a metal material, a combination of metal materials, or a combination of metal and non-metal materials. To be more specific, the solder materials may be Al, Sn, Ni, Au, Ag, lead (Pb), bismuth (Bi), Cu, or combinations thereof. In some embodiments, the solder bumps 111 may include metal powders. For example, the solder bumps 111 may be sintered metal powders. In some other embodiments, the solder bumps 111 may include metal powders and an adhesive material gluing the metal powders. The adhesive material should be sticky enough to glue the metal powders together before, during and after a subsequent heating process of the solder bumps 111. In other words, the adhesive material should not volatilize completely during the heating process of the solder bumps 111. In addition, the adhesive material may include a thermal conductive material, which allows for an efficient convection heat transfer within the solder bumps 111 during the heating process. In some alternative embodiments, the adhesive material may include a polar material, which further facilitates a heating process of the solder bumps 111 when they are exposed to microwave radiation subsequently, since the adhesive material may absorb microwave energy and may thus be particularly heated.

Next, as shown in FIG. 1C, a flux material 112 is coated onto surfaces of the solder bumps 111. The flux material 112 may facilitate a subsequent heating process of the solder bumps 111 and then may enable sufficient electrical connection between the substrate 100 and the at least one electronic component 110 through the solder bumps 111. The flux material 112 includes a significant amount of a polar material or polar materials, which can be particularly heated when exposed to microwave radiation. Furthermore, in some embodiments, the flux material 112 includes a polar material or polar materials having a degree of polarization higher than that of the solder bumps 111. Therefore, when exposed to microwave radiation, the flux material 112 may be heated to a higher temperature compared with the solder bumps 111, which enables a sufficient convection heat transfer from the flux material 112 to the solder bumps 111. In some embodiments, the flux material 112 may include one or more materials selected from the following group: nonylphenol ethoxylate, glyceryl monostearate, acid activator, water and mineral salt. In a preferred embodiment, the flux material 112 may include between 40 wt. % and 70 wt. % of nonylphenol ethoxylate, between 10 wt. % and 30 wt. % of glyceryl monostearate, between 3 wt. % and 10 wt. % of acid activator, between 3 wt. % and 10 wt. % of water, and between 4 wt. % and 15 wt. % of mineral salt.

In the embodiment shown in FIG. IC, the flux material 112 is coated onto bottom surfaces of the solder bumps 111. In some other embodiments, the flux material 112 may be coated onto whole spherical surfaces of the solder bumps 111 which are exposed from the back surface of the electronic component 110, so as to increase contact areas between the flux material 112 and the solder bumps 111, therefore enhancing the convection heat transfer from the flux material 112 to the solder bumps 111.

Next, as shown in FIG. 1D, the at least one electronic component 110 is disposed onto the front surface of the substrate 100 via the solder bumps 111 which are coated with the flux material 112. The flux material 112 lies between the bottom surfaces of the solder bumps 111 and top surfaces of the conductive pads. It can be appreciated that the flux material 112 may flow slightly towards the conductive pads due to surface tension, but a significant portion of the surfaces of the solder bumps 111 may still be coated with the flux material 112.

Next, as shown in FIG. 1E, a microwave source is placed above the electronic component 110, and then microwave radiation is applied from the microwave source to the electronic component 110 to heat the solder bumps 111 through the flux material 112. The electronic component 110 which may generally include non-polar material(s) may not absorb or may barely absorb the microwave energy, and thus the microwave can penetrate the electronic component 110 and the solder bumps 111 and reach the flux material 112. In some other embodiments, the microwave source is placed at one or more lateral sides of the electronic component 110. The microwave radiation may be applied from the microwave source to the solder bumps 111 and the flux material 112 from lateral sides. Therefore, the microwave may interact with the solder bumps 111 and the flux material 112 more directly without first going through the electronic component 110, which may increase energy absorption efficiency. It can also be appreciated that positions where the microwave source is placed may vary according to actual layouts of the electronic device. For example, one or more microwave sources may be inclined for 30 degrees, 45 degrees, 60 degrees or any other suitable degrees with respect to the front surface of the substrate 100.

Still referring to FIG. 1E, when the solder bumps 111 and the flux material 112 are exposed to the microwave radiation, the dipoles within the polar molecules of the flux material 112 are sensitive to an electrical field of the microwave and may rotate to align themselves with a direction of the electrical field. The electrical field of the microwave is periodically changing, which may prompt the dipoles to rotate frequently. As a result, the dipoles may collide with each other when they attempt to follow the electrical field, which generates heat energy and results in a high temperature rise of the flux material 112, e.g., to a temperature higher than a melting temperature of the solder bumps 111. In addition, the solder bumps 111, especially the solder bumps 111 which include metal powders, may also absorb microwave energy to generate heat, which results in a moderate temperature rise of the solder bumps 111. With the temperature rise of the flux material 112, a part of the heated flux material 112 may volatilize first, and the heat generated in the flux material 112 may be convectively transferred to the solder bumps 111, which brings about a further temperature rise of the solder bumps 111. Then the temperature of the solder bumps 111 may rise over the melting temperature of the solder bumps 111, which induces the solder bumps 111 to melt and be reshaped in a reflowing process of the solder bumps 111. Finally, as shown in FIG. 1F, the flux material 112 may volatilize completely, allowing the reflowed solder bumps 111 to form electronical connection between the interconnect wires 101 and the electronic component 110. In some other embodiments, only a part of the flux material 112 may volatilize, and finally the remaining flux material 112 may be removed from the solder bumps 111. In some alternative embodiments, finally the remaining flux material 112 and the solder bumps 111 may melt together to form electronical connection between the interconnect wires 101 and the electronic component 110.

During the microwave radiation process, the flux material 112 may be heated to reach a high temperature to provide enough heat to the solder bumps 111 through convection, while at the same time, the flux material 112 should not be overheated to avoid complete volatilization of the flux material 112 before sufficient reflowing of the solder bumps 111. In other words, the temperature of the flux material 112 should be controlled within an appropriate range. In some embodiments, the appropriate range may be between 120 C° and 350 C° when rosin is used, especially for tin solder bumps which may be melted above 230 C°. In some other embodiments, resin flux or other suitable polar flux materials may be used, and the appropriate range may range from the melting temperature of the solder material to a temperature equal to or slightly greater than the vaporization temperature of the flux material 112, e.g., from 10° C. higher than the melting temperature of the solder material to 10° C. higher than the vaporization temperature of the flux material 112, or to 10° C. lower than the vaporization temperature of the flux material 112, for example. In some embodiments, the microwave radiation may be applied intermittently to control the temperature of the heated flux material 112, e.g., the microwave radiation may be applied for a certain time duration such as 10 seconds to 2 minutes and then be suspended for another certain time duration such as 5 seconds to 30 seconds, and such cycle may be repeated for several times, depending on the reflowing of the solder bumps 111. It can be appreciated that the certain time duration may be several seconds to several minutes, depending on the actual needs of the heating process, such as the specific composition of the flux material 112 and/or the solder bumps 111, the number and size of the solder bumps 111, and/or the power of the microwave radiation. In some other embodiments, a temperature sensor, e.g., an infrared temperature sensor or an infrared image array, may be used to monitor the temperature of the flux material 112 or the solder bumps 111, and may then provide the real-time temperature measurement(s) to a controller for the microwave source to adjust the power and/or duration of the microwave radiation, for example. In some preferred embodiments, the substrate 100 as well as the electronic component 110 mounted thereon may be placed in an atmosphere with a high ambient temperature to avoid that during the heating process too much heat is transferred from the flux material 112 and/or solder bumps 111 to the substrate 100 and/or the electronic component 110 due to a significant temperature difference between them and the solder bumps 111/flux material 112. For example, the ambient temperature may be 10° C. to 150° C., or preferably 10° C. to 50° C., or more preferably 10° C. to 30° C., lower than the melting temperature of the solder bumps 111.

Furthermore, in this embodiment, the microwave radiation is applied at variable frequencies during the microwave radiation step. By sweeping a range of frequencies rapidly, the microwave radiation process may increase the uniformity of microwave energy in comparison with a fixed-frequency microwave. The microwave radiation may be applied at a frequency ranging between 1 GHz and 10 GHz. The microwave source may be set at a power ranging between 100 W and 2000 W. In other embodiments, the microwave radiation may be applied at a frequency higher than 10 GHz or with a microwave source power higher than 1000 W, which allows for a more rapid temperature rise of the solder bumps 111 and the flux material 112. In addition, the microwave radiation may last for a minimum duration, such as 1 minute to allow for sufficient reflowing of the solder bumps 111 and complete volatilization of the flux material 112, thereby forming effective electrical connection between the electronic components 110 and the interconnect wires 101 within the substrate 100 and avoiding further cleaning the residual flux material after the reflowing process. It can also be appreciated that the frequency, power and duration of the microwave radiation may be selected according to actual needs of the reflowing process of the solder bumps 111. At the same time, since the molecules in non-polar materials are not sensitive to electrical fields of the microwaves, the substrate 100 and electronic component 110 may not be heated or may barely be heated by the microwave radiation when they are exposed to the microwave field together with the solder bumps 111 and the flux material 112. In addition, the interconnect wires 101 which is embedded within the substrate 100 and metal layers which may be included within the electronic component 110 may reflect the microwave and may barely generate heat energy. In this way, the solder bumps 111 and the flux material 112 are selectively heated by the microwave radiation. This heating mechanism may offer multiple advantages to the reflowing process of the solder bumps 111. Firstly, instead of a traditional heating process applied to the whole electronic device, the selective heating of the solder bumps 111 and the flux material 112 by microwave radiation may reduce the warpage issues of the substrate 100 and electronic component 110 since the substrate 100 and electronic component 110 are barely heated by the microwave radiation. Secondly, the microwave can penetrate the flux material 112 and the solder bumps 111 to supply energy, and thus the heat can be generated throughout the solder bumps 111 in a volumetric manner, which allows for a more uniform heat distribution from surfaces to interiors of the solder bumps 111. Thirdly, the microwave induces molecular rotation without destroying molecular bonds due to low energy per photon, which may have little influence on the internal structures of the components of the electronic device. Fourthly, the microwave heating can be started and/or ended quickly, which may reduce the heating duration.

In an alternative embodiment, before applying the microwave radiation, at least one additional electronic component may be provided with additional solder bumps mounted on its back surface, and the additional solder bumps are coated with an additional flux material of at least a polar material, and the at least one additional electronic component includes at least a non-polar material. Then the at least one additional electronic component may be mounted onto the top surface of the electronic component 110 via additional solder bumps and additional wires embedded within the electronic component 110, thereby forming an electronic module with double layers on the substrate 100. Afterwards, the microwave radiation may be applied to heat the solder bumps 111 and the additional solder bumps through the flux material 112 and the additional flux material selectively, while at the same time the substrate 100, the electronic component 110 and the additional electronic component are barely heated by the microwave radiation. Instead of a traditional heating process applied to the whole electronic device, the selective heating of the solder bumps 111, the additional solder bumps, the flux material 112 and the additional flux material by microwave radiation may reduce the warpage issues of the substrate 100, electronic component 110 and the additional electronic components. In addition, since the heating process of the flux material 112 and the additional flux material are conducted simultaneously, the additional solder bumps and the solder bumps 111 may also be heated simultaneously, which induces a more uniform reflowing process of the solder bumps within the electronic module with double layers. It can be appreciated more than two layers of solder bumps may be reflowed simultaneously when desired.

After the reflowing of the solder bumps 111 by the microwave radiation, an encapsulant layer may be formed on the substrate 100 to encapsulate the at least one electronic component 110, therefore forming an electronic package device. In some other embodiments, the method for forming the electronic device may not include the process of forming the encapsulant layer.

In some embodiments, the method can be used in forming an electronic device with a reduced size and complex structures, such as a system-in-package (SIP) device with various electronic components 110. In some other embodiment, the electronic device can be applied in any devices which desire reduced warpage issues. For example, the electronic device may be a double-sided electronic device, and accordingly, a back surface of the substrate may also serve as another platform where electronic component(s) may be mounted on via solder bumps and a coated flux material. The solder bumps and the flux material on the front surface and the back surface of the substrate may be heated by the microwave radiation at the same time to form electrical connection between the electronic components and the interconnect wires within the substrate.

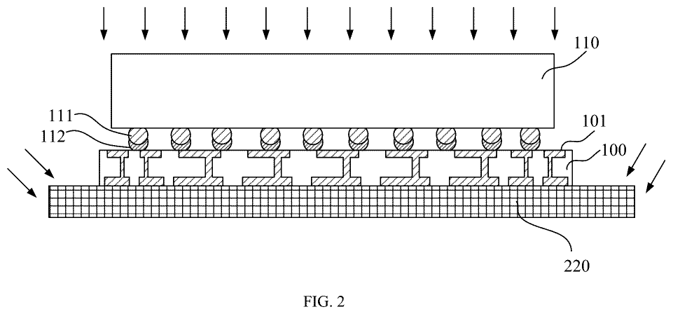

FIG. 2 illustrates a microwave radiation step of a method for forming an electronic device according to a second embodiment of the present application. The step illustrated in FIG. 2 may be implemented after the steps illustrated in FIGS. 1A to 1D have been performed, instead of the steps illustrated in FIGS. 1E and 1F, as an alternative embodiment to the embodiment shown in FIGS. 1A to 1F.

In the embodiment shown in FIG. 2, after the at least one electronic component 110 is disposed onto the front surface of the substrate 100 via the solder bumps 111 and the flux material 112, the substrate 100 is loaded onto a susceptor 220 with a back surface of the substrate 100 in contact with the susceptor 220. The susceptor 220 may include a polar material, a combination of polar materials, or a combination of polar and non-polar materials, which can be heated by microwave radiation. In addition, the susceptor 220 may include thermal conductive material(s), which allows for a sufficient convection heat transfer from the susceptor 220 to the flux material 112 and the solder bumps 111 or alleviation of heat dissipation of the flux material 112 and the solder bumps 111 through the backside of the substrate 100. In some embodiments, a significant portion (e.g., greater than 50 wt. %, 60 wt. %, 70 wt. %, 80 wt. %, 90 wt. %, 95 wt. % or 99 wt. %) of the susceptor 220 is formed of polar material(s), which offers a better heating performance when exposed to microwave radiation. To be more specific, the susceptor 220 may include at least one polar material selected from a group of silicon carbide, graphite, charcoal with polarity and carbon with polarity. In some other embodiments, the susceptor 220 may include a non-polar base coated with polar material(s) or distributed with polar materials(s), which may lower the requirement on materials of the susceptor 220 and achieve a better mechanical support and a reduced cost during the heating step of the solder bumps 111 and the flux material 112, if appropriate materials for the non-polar base are used. Particularly, the non-polar base may include a silicon wafer or silicon powders, and the polar coating may include at least one polar material selected from a group of silicon carbide, graphite, charcoal with polarity or carbon with polarity.

Next, still referring to FIG. 2, microwave radiation is applied to the at least one electronic component 110, which heats the solder bumps 111 through the flux material 112. At the same time, the susceptor 220 is also exposed to the microwave radiation, where the microwave radiation may penetrate the at least one electronic component 110 and the substrate 100, and finally reach the susceptor 220. In addition, the microwave radiation may also directly reach the susceptor 220 from lateral surfaces and a bottom surface of the susceptor 220 which are not blocked by the substrate 100. Since the susceptor 220 is at least partially formed of a polar material, dipoles within polar molecules of the susceptor 220 are sensitive to an electrical field of the microwave, which may generate heat energy in the susceptor 220. In some embodiments, the heat generated in the susceptor 220 may be convectively transferred to the flux material 112 and the solder bumps 111, which provides additional heat energy to promote a reflowing process for the solder bumps 111. In this way, the flux material 112 and solder bumps 111 may be heated through a hybrid heating mechanism which incorporates the direct microwave heating and the convection heat transfer from the susceptor 220. Furthermore, the heated susceptor 220 may alleviate heat dissipation of the flux material 112 and the solder bumps 111 through the substrate 100, which also promotes the reflowing process. Therefore, the reflowing process may have a higher energy efficiency, which may lead to a lower energy demand from the microwave source. In addition, the flux material 112 and a bottom part of the solder bumps 111 with less exposure to the microwave radiation due to shielding of the electronic component 110 may receive more heat energy convectively transferred from the susceptor 220, and the flux material 112 and the solder bumps 111 may be heated in a more uniform and controlled way with fewer defects. In short, an excess amount of microwave energy which cannot be absorbed by the flux material 112 and the solder bumps 111 may be collected by the susceptor 220 and converted into heat, which, in turn, helps for the reflowing process of the solder bumps 111. Then the solder bumps 111 may melt and be reshaped in the reflowing process, and the reflowed solder bumps 111 may form electronical connection between the interconnect wires 101 and the electronic component 110. In some embodiments, the susceptor 220 may include at its bottom side a film or a plate which can reflect microwave upward. During the reflowing process, the reflected microwave may again penetrate the susceptor 220 and generate heat there, or even penetrate the susceptor 220 and reach the flux material 112 and the solder bumps 111 to heat the flux material 112 and the solder bumps 111. In some embodiments, the susceptor 220 which is heated by the microwave radiation may reach a temperature ranging between 50 C° and 200 C°. In a preferred embodiment, the microwave radiation is applied such that a temperature of the susceptor 220 may range between 50 C° and 120 C°, which alleviates warpage of the device in a most controlled way along with a sufficient reflowing process of the solder bumps 111.

In some other embodiments, the susceptor 220 may be attached on a top surface of the electronic component 110. When the microwave radiation is applied, the susceptor 220 which includes at least a polar material may be heated. Since the susceptor 220 is in direct contacted with the electronic component 110, the heated susceptor 220 may allow for more efficient convection heat transfer to the flux material 112 and the solder bumps 111 as well as alleviation of heat dissipation of the flux material 112 and the solder bumps 111, thereby promoting the reflowing process of the solder bumps 111. In addition, since the substrate 100 may not experience heat transfer, the warpage of the substrate 100 may be avoided or alleviated. In some embodiments, the susceptor 220 which is heated by the microwave radiation may reach a temperature ranging between 50 C° and 200 C°. In a preferred embodiment, the microwave radiation is applied such that a temperature of the susceptor 220 may range between 50 C° and 120 C°, which alleviates warpage of the device.

While the exemplary method for forming an electronic device of the present application is described in conjunction with corresponding figures, it will be understood by those skilled in the art that modifications and adaptations to the method for forming an electronic device may be made without departing from the scope of the present invention.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A method for forming an electronic device, the method comprising:
providing a substrate having a front surface, wherein the substrate comprises at least a non-polar material;
providing at least one electronic component with solder bumps mounted on its back surface, wherein the solder bumps are coated with a flux material comprising at least a polar material, and the at least one electronic component comprises at least a non-polar material;
disposing the at least one electronic component onto the front surface of the substrate via the solder bumps; and
applying microwave radiation to the at least one electronic component to heat the solder bumps through the flux material.

2. The method of claim 1, wherein the solder bumps comprise metal powders.

3. The method of claim 1, wherein the solder bumps comprise metal powders and an adhesive material gluing the metal powders.

4. The method of claim 3, wherein the adhesive material comprises a thermal conductive material.

5. The method of claim 4, wherein the adhesive material comprises a polar material.

6. The method of claim 1, wherein the flux material comprises at least a polar material having a degree of polarization higher than that of the solder bumps.

7. The method of claim 6, wherein the flux material comprises one or more materials selected from the following group: nonylphenol ethoxylate, glyceryl monostearate, acid activator, water and mineral salt.

8. The method of claim 7, wherein the flux material comprises between 40 wt. % and 70 wt. % of nonylphenol ethoxylate, between 10 wt. % and 30 wt. % of glyceryl monostearate, between 3 wt. % and 10 wt. % of acid activator, between 3 wt. % and 10 wt. % of water, and between 4 wt. % and 15 wt. % of mineral salt.

9. The method of claim 1, wherein the microwave radiation is applied at a frequency ranging between 1 GHz and 10 GHz.

10. The method of claim 1, wherein the microwave radiation is applied at variable frequencies during the step of applying the microwave radiation to the at least one electronic component.

11. The method of claim 1, wherein applying microwave radiation to the at least one electronic component comprises:
placing a microwave source above a front surface of the at least one electronic component; and
applying the microwave radiation from the microwave source to the at least one electronic component.

12. The method of claim 1, wherein the at least one electronic component comprises a semiconductor package.

13. The method of claim 1, wherein the method further comprises:
forming an encapsulant layer on the substrate to encapsulate the at least one electronic component.

14. The method of claim 1, wherein before applying microwave radiation to the at least one electronic component, the method further comprises:
loading the substrate onto a susceptor, and the susceptor comprises at least a polar material.

15. The method of claim 14, wherein the susceptor comprises a thermal conductive material or thermal conductive materials.

16. The method of claim 14, wherein the susceptor comprises at least one polar material selected from a group of silicon carbide, graphite, charcoal with polarity and carbon with polarity.

17. The method of claim 14, wherein the susceptor comprises a non-polar base coated with a polar material.

18. The method of claim 14, wherein loading the substrate onto a susceptor comprises:
loading the substrate onto the susceptor with a back surface of the substrate in contact with the susceptor.

19. The method of claim 14, wherein loading the substrate onto a susceptor comprises:
loading the substrate onto the susceptor with a top surface of the at least one electronic component in contact with the susceptor.

20. An electronic device which is formed using the method of claim 1.
